(19) United States
(12) Patent Application Publication
(10) Pub. No.: US 2016/0260810 A1
(43) Pub. Date: Sep. 8, 2016

(54) SEMICONDUCTOR DEVICE

(71) Applicant: KABUSHIKI KAISHA TOSHIBA, Tokyo (JP)

(72) Inventor: Masaki SAKAI, Kanazawa Ishikawa (JP)

(21) Appl. No.: 14/831,741

(22) Filed: Aug. 20, 2015

(30) Foreign Application Priority Data
Mar. 4, 2015 (JP) 2015-042851

(51) Int. Cl. H01L 29/417; H01L 21/288; H01L 29/66; H01L 29/45; H01L 29/739

(52) U.S. Cl. CPC H01L 29/41708; H01L 29/45; H01L 29/7397; H01L 29/66348; H01L 21/288

(57) ABSTRACT

According to an embodiment, a semiconductor device includes a semiconductor layer, a first metal layer formed over the semiconductor layer, a barrier film formed over the first metal layer and having an ionization tendency lower than an ionization tendency of the first metal layer, a second metal layer formed over the barrier film and having an ionization tendency higher than an ionization tendency of the metal film, and a third metal layer formed over the second metal layer and having an ionization tendency lower than an ionization tendency of the second metal layer.

### CROSS-REFERENCE TO RELATED APPLICATION

This application is based upon and claims the benefit of priority from Japanese Patent Application No. 2015-042851, filed Mar. 4, 2015, the entire contents of which are incorporated herein by reference.

### FIELD

Embodiments described herein relate to a semiconductor device.

### BACKGROUND

A technique for forming a plating film on a surface electrode of a semiconductor chip is known. The plating film is formed so as to improve adhesiveness between a solder layer to be formed on the surface electrode and the surface electrode.

However, in some cases the plating film may enter or penetrate the surface electrode partially at the time of forming the plating film. When the degree of penetration is increased, there is a possibility that short-circuiting occurs between the plating film and a wiring line or between the plating film and the underlying substrate. Further, when the degree of penetration is increased, there is a possibility that mobile ions in a plating liquid contaminate an element region of the device such that an operational characteristic of the element changes.

### DESCRIPTION OF THE DRAWINGS

FIG. 1 is a schematic cross-sectional view of a semiconductor device according to a first embodiment.

FIG. 2 is a schematic cross-sectional view of a semiconductor device according to a comparison example.

FIG. 3 is an explanatory view of a failure mode of the semiconductor device according to the comparison example.

FIG. 4 is an explanatory view for explaining the manner of operation and advantageous effects of the semiconductor device according to the first embodiment.

FIG. 5 is a schematic cross-sectional view of a semiconductor device according to a second embodiment.

FIG. 6 is a schematic cross-sectional view of a semiconductor device according to a third embodiment.

### DETAILED DESCRIPTION

In general, according to one embodiment, a semiconductor device includes: a semiconductor layer; a first metal layer formed over the semiconductor layer; a barrier film formed over the first metal layer and having an ionization tendency lower than an ionization tendency of the first metal layer; a second metal layer formed over the barrier film and having an ionization tendency higher than an ionization tendency of the metal film; and a third metal layer formed over the second metal layer and having an ionization tendency lower than an ionization tendency of the second metal layer.

Hereinafter, exemplary embodiments are explained by reference to drawings. In the explanation made hereinafter, identical or substantially similar components are given the same reference symbols, and once explained, the explanation of such components may be omitted when appropriate.

In this disclosure, the descriptions “n⁺-type”, “n-type”, and “n⁻-type” mean that the concentration of an n-type dopant is lowered in this order. Further, the descriptions of “p⁺-type”, “p-type”, “p⁻-type” mean that the concentration of a p-type dopant is lowered in this order.

### First Embodiment

A semiconductor device according to this first embodiment includes: a semiconductor layer; a first metal layer formed over the semiconductor layer; a metal film formed over the first metal layer and having an ionization tendency lower than that of the first metal layer; a second metal layer formed over the metal film and having an ionization tendency higher than that of the metal film; and a third metal layer formed over the second metal layer and having an ionization tendency lower than that of the second metal layer.

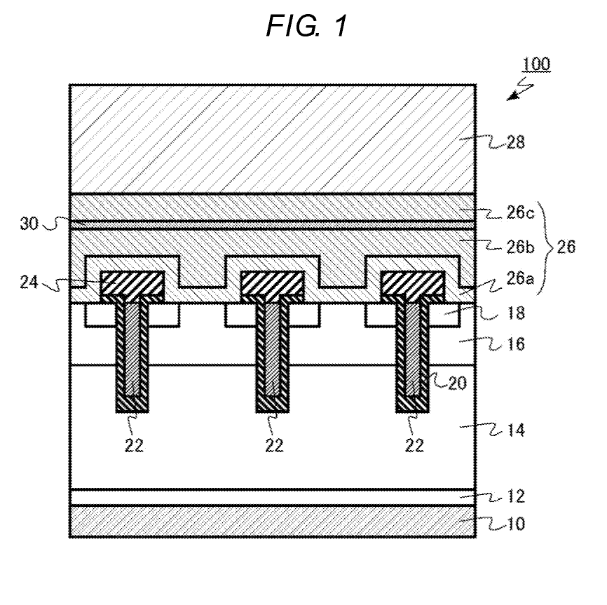

FIG. 1 is a schematic cross-sectional view of the semiconductor device according to this first embodiment. The semiconductor device 100 is an IGBT (Insulated Gate Bipolar Transistor) having a trench gate structure. The IGBT 100 is mounted on a package having a double-side cooling structure.

The IGBT 100 includes: a collector electrode (back surface electrode) 10; a p⁺-type collector layer 12; an n⁻-type base layer 14; a p-type base layer 16; n⁺-type emitter layers 18; gate insulation films 20; gate electrodes 22; interlayer insulation films 24; an emitter electrode (front surface electrode) 26; a surface metal layer (third metal layer) 28; and a barrier layer 30. The p-type base layer 16 and the n⁺-type emitter layer 18 are semiconductor layers.

The emitter electrode (front surface electrode) 26 includes: a barrier metal 26a; a lower metal layer (first metal layer) 26b; and an upper metal layer (second metal layer) 26c. The barrier layer 30 is disposed between the lower metal layer (first metal layer) 26b and the upper metal layer (second metal layer) 26c.

The p⁺-type collector layer 12, the n⁻-type base layer 14, and the p-type base layer 16 are made of single crystal silicon (Si), for example. In the respective layers, a p-type dopant is B (boron), for example, and an n-type dopant is phosphorus (P) or arsenic (As), for example.

The collector electrode 10 is made of metal, for example. The p⁺-type collector layer 12 is formed on the collector electrode 10.

The n⁻-type base layer 14 is formed on the p⁺-type collector layer 12. The n⁻-type base layer 14 functions as a drift layer of the IGBT 100. The p-type base layer 16 is formed on the n⁻-type base layer 14.

The IGBT 100 includes the gate electrodes 22. The gate insulation film 20 is interposed between the gate electrode 22 and the n⁻-type base layer 14 as well as between the gate electrode 22 and the p-type base layer 16.

The IGBT 100 may also be considered to correspond to a MOSFET (Metal Oxide Semiconductor Field Effect Transistor) structure where the n⁺-type emitter layer 18 forms a source, the n⁻-type base layer 14 forms a drain, the p-type base layer 16 forms a base, and the gate electrode 22 forms a gate.

The gate electrode 22 is made of polycrystalline silicon containing an n-type dopant, for example. The gate insulation film 20 is formed of a silicon oxide film, for example.

The n⁺-type emitter layers 18 are selectively formed on a surface of the p-type base layer 16. A concentration of n-type dopant in the n⁺-type emitter layer 18 is higher than a concentration of n-type dopant in the n⁻-type base layer 14.

The interlayer insulation film 24 is formed on the gate electrode 22. The interlayer insulation film 24 is formed of a silicon oxide film, for example.

The emitter electrode 26 is formed on the interlayer insulation films 24. The emitter electrode 26 is in contact with the p-type base layer 16 and the n⁺-type emitter layers 18. The emitter electrode 26 and the p-type base layer 16 are in an ohmic contact with each other, and the emitter electrode 26 and the n⁺-type emitter layer 18 are in an ohmic contact with each other, for example.

The barrier metal 26a is a stacked film formed of a titanium (Ti) layer and a titanium nitride (TiN) layer, for example. The barrier metal 26a is formed by a sputtering method, for example. The barrier metal 26a may be formed also by a CVD (Chemical Vapor Deposition) method. A film thickness of the barrier metal 26a is 0.01 μm or more and 1 μm or less, for example.

The lower metal layer 26b comprises aluminum (Al), for example. The lower metal layer 26b can made of aluminum, aluminum-silicon (AlSi) or aluminum-silicon-copper) (AlSiCu), for example.

The upper metal layer 26c comprises aluminum (Al), for example. The upper metal layer 26c is made of aluminum, aluminum-silicon (Si) (AlSi) or aluminum-silicon-copper (Cu) (AlSiCu), for example.

The lower metal layer 26b and the upper metal layer 26c are formed by a sputtering method, for example. The lower metal layer 26b and the upper metal layer 26c may be formed also by a CVD method.

A film thickness of the emitter electrode 26 is 3 μm or more and 8 μm or less, for example.

The barrier layer 30 is a metal film having an ionization tendency lower than that of the lower metal layer 26b. The barrier layer 30 is also a metal film having an ionization tendency lower than that of the upper metal layer 26c. In other words, the upper metal layer 26c is a film having an ionization tendency higher than that of the barrier layer 30.

The barrier layer 30 is made of titanium, for example. Besides titanium, titanium nitride (TiN), tungsten (W), tungsten nitride (WN), molybdenum (Mo), nickel (Ni), vanadium (V), copper (Cu) or the like may be used as a material for forming the barrier layer 30.

A film thickness of the barrier layer 30 is 0.01 μm or more and 1 μm or less, for example.

The surface metal layer (third metal layer) 28 having an ionization tendency lower than that of the upper metal layer 26c is formed on the upper metal layer 26c. The surface metal layer (third metal layer) 28 is a plating film formed by a plating method. The surface metal layer 28 is formed by an electroless plating method, for example. The surface metal layer 28 comprises a nickel film, for example.

The surface metal layer 28 has a function of enhancing adhesiveness between a solder layer (not shown in the drawing) formed so as to connect a heat radiation plate (not shown in the drawing) to the emitter electrode 26, for example.

A film thickness of the surface metal layer (third metal layer) 28 is 3 μm or more and 8 μm or less, for example. The film thickness of the surface metal layer (third metal layer) 28 is larger than a film thickness of the barrier layer 30.

Next, the manner of operation and advantageous effects of the semiconductor device according to this embodiment are explained.

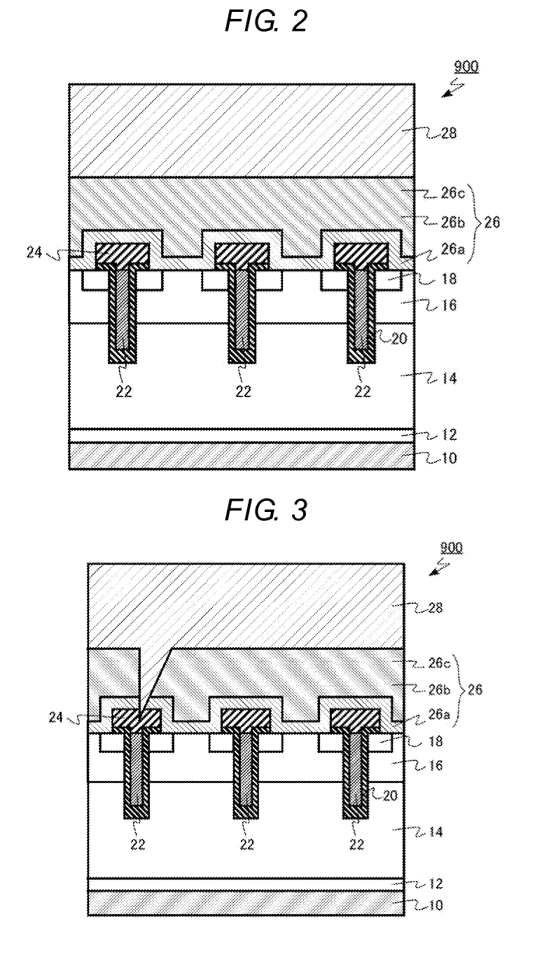

FIG. 2 is a schematic cross-sectional view of a semiconductor device according to a comparison example. The semiconductor device 900 according to the comparison example is an IGBT having a trench gate structure.

The IGBT 900 of the comparison example has substantially the same structure as the IGBT 100 except that the IGBT 900 does not include the barrier layer 30.

FIG. 3 is an explanatory view of a failure mode of the semiconductor device according to the comparison example. As shown in FIG. 3, there may be a case where a plating film (e.g., surface metal layer 28) penetrates into and/or through emitter electrode 26 at the time of forming surface metal layer 28 by a plating method. When the degree of penetration is increased, there is a possibility that short-circuiting occurs between the plating film and a gate electrode 22 or between the plating film and a substrate (e.g., layer 28 may contact and/or penetrate semiconductor regions 18 and/or 16).

Further, when the degree of penetration is increased, mobile ions such as sodium ions in a plating liquid enter an element region thus may give rise to a possibility that a characteristic of the element changes via contamination. For example, there is a possibility that a threshold voltage of the MOSFET changes due to contamination of the element region.

The penetrations of the plating film becomes particularly conspicuous when a fragile portion is present in the emitter electrode 26. The fragile portion may be formed at the time of forming the film 26. Here, “a fragile portion” corresponds to an indentation formed on a surface of the emitter electrode 26 or a portion of the emitter electrode 26 having lower density than the bulk of the emitter electrode 26, for example.

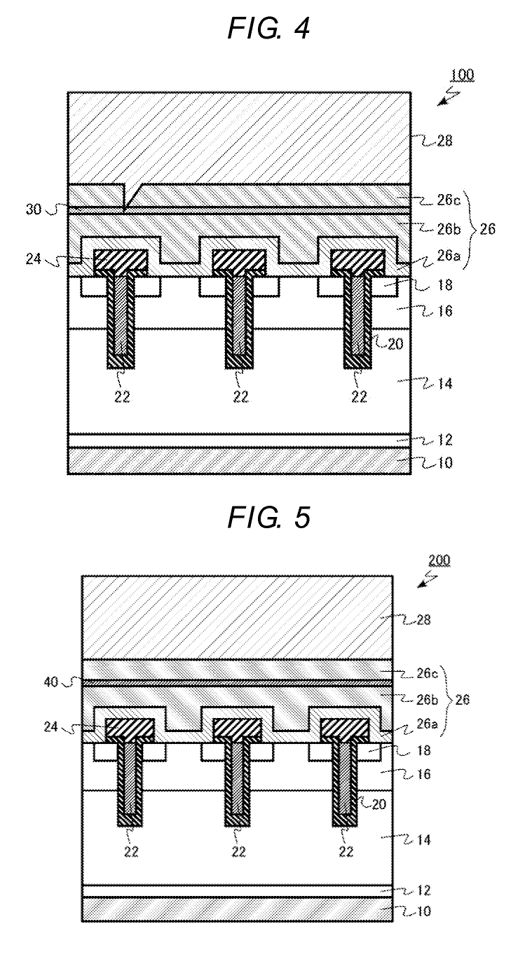

FIG. 4 is an explanatory view for explaining the manner of operation and advantageous effects of the semiconductor device according to this first embodiment. The IGBT 100 includes the barrier layer 30 having an ionization tendency lower than those of the upper metal layer 26c and the lower metal layer 26b. The barrier layer 30 has an ionization tendency lower than those of the upper metal layer 26c and the lower metal layer 26b and hence, the barrier layer 30 is minimally displaced by the plating film.

Accordingly, as shown in FIG. 4, even when a portion of the upper metal layer 26c is displaced by the plating film due to a displacement reaction such that the plating film penetrates the upper metal layer 26c, the penetration of the plating film may be stopped by the barrier layer 30. Accordingly, short-circuiting between the plating film and a conductive line such as the gate electrode 22 and/or short-circuiting (or other contact) between the plating film and the substrate may be suppressed. Further, even when the plating film penetrates, a minimum distance of separation between the plating film and the element region may be ensured by a film thickness of the lower metal layer 26b and hence, it is possible to prevent mobile ions from the plating solution from entering the element region and changing the electrical characteristic thereof.

To prevent the plating film from penetrating to the element region and/or contacting a gate electrode element, it is desirable that an ionization tendency of the barrier layer (metal film) 30 be lower than an ionization tendency of the surface metal layer (third metal layer) 28. For example, it is desirable that the lower metal layer 26b and the upper metal layer 26c be made of aluminum, the barrier layer be made of copper, and the surface metal layer 28 be made of nickel.

According to this first embodiment, it is possible to realize the IGBT 100 where penetration of the plating film through a metal barrier layer used in forming the emitter electrode is suppressed.

### Second Embodiment

A semiconductor device according to this embodiment includes: a semiconductor layer; a first metal layer formed over the semiconductor layer; a semiconductor film formed over the first metal layer; a second metal layer formed over the semiconductor film; a third metal layer formed over the second metal layer and having an ionization tendency lower than that of the second metal layer.

A semiconductor device according to this second embodiment has substantially the same structure as the IGBT 100 excepting that the semiconductor device according to this second embodiment includes a semiconductor film (e.g., film 40) in place of a metal film (e.g., film 30).

FIG. 5 is a schematic cross-sectional view of the semiconductor device according to this second embodiment. The semiconductor device 200 according to this second embodiment is an IGBT having a trench gate structure.

An emitter electrode (front surface electrode) 26 includes: a barrier metal 26a; a lower metal layer (first metal layer) 26b; and an upper metal layer (second metal layer) 26c. A barrier layer (semiconductor film) 40 is disposed between the lower metal layer (first metal layer) 26b and the upper metal layer (second metal layer) 26c.

The barrier layer 40 is a semiconductor film to which conductivity is imparted. The barrier layer 40 is made of polycrystalline silicon containing phosphorus (P), arsenic (As), or boron (B) as a dopant, for example.

The barrier layer 40 is formed by a CVD method, for example. A film thickness of the barrier layer 40 is 0.01 μm or more and 1 μm or less, for example.

The barrier layer 40 formed of a semiconductor film is less likely to be displaced by (or otherwise react with) the plating film than the upper metal layer 26c and the lower metal layer 26b.

It is thus possible to provide the IGBT 200 in which penetration of the plating film through the emitter electrode 26 is reduced.

### Third Embodiment

A semiconductor device according to this third embodiment includes: a semiconductor layer; a first metal layer formed over the semiconductor layer and containing aluminum (Al); a barrier layer formed over the first metal layer and containing a material selected from titanium (Ti), titanium nitride (TiN), tungsten (W), tungsten nitride (WN), molybdenum (Mo), nickel (Ni) and copper (Cu); a second metal layer formed over the barrier layer and containing aluminum (Al); and a plating film formed over the second metal layer and containing nickel (Ni).

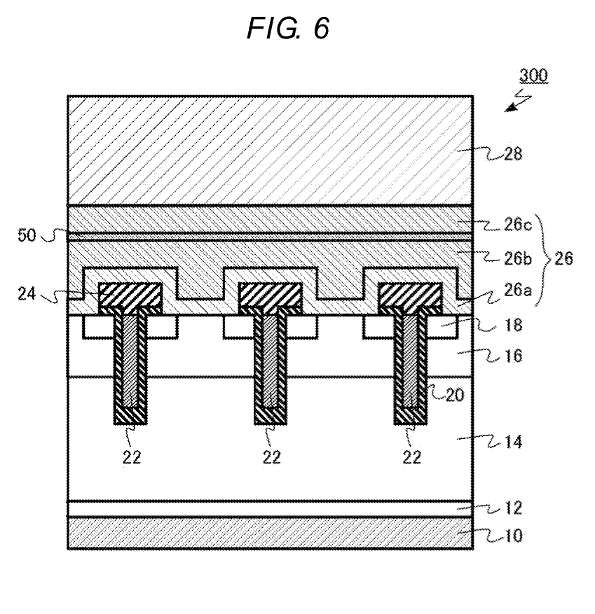

FIG. 6 is a schematic cross-sectional view of a semiconductor device according to this third embodiment. The semiconductor device 300 according to this third embodiment is an IGBT having a trench gate structure.

An emitter electrode (front surface electrode) 26 includes: a barrier metal 26a; a lower metal layer (first metal layer) 26b; and an upper metal layer (second metal layer) 26c. A barrier layer 50 is disposed between the lower metal layer (first metal layer) 26b and the upper metal layer (second metal layer) 26c.

The lower metal layer 26b is made of metal containing aluminum (Al). The lower metal layer 26b is made of aluminum, aluminum containing silicon (Si) (AlSi) or aluminum containing silicon (Si) and copper (Cu) (AlSiCu), for example.

The upper metal layer 26c is made of metal containing aluminum (Al). The upper metal layer 26c is made of aluminum, aluminum containing silicon (Si) (AlSi) or aluminum containing silicon (Si) and copper (Cu) (AlSiCu), for example.

The barrier layer 50 is a film containing, for example, one or more metal selected from a group consisting of titanium (Ti),), tungsten (W), molybdenum (Mo), nickel (Ni), and copper (Cu). The barrier layer 50 may also include or be titanium nitride (TiN) and/or tungsten nitride (WN).

A surface metal layer (plating film) 28 having an ionization tendency lower than that of the upper metal layer 26c is formed on the upper metal layer 26c. The surface metal layer 28 is a plating film containing nickel.

The barrier layer 50 is less likely to be displaced by (or otherwise react with) the plating film than the upper metal layer 26c.

Due to such a structure, it is possible to realize the IGBT 300 where penetration of the plating film through the emitter electrode 26 is reduced.

Although the explanation has been made by taking an IGBT as an example of a semiconductor device in the first to third embodiments, the present disclosure is also applicable to other semiconductor devices such as a metal-oxide-semiconductor field effect transistor (MOSFET) or a PIN diode.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor layer;
a first metal layer on the semiconductor layer;
a barrier film on the first metal layer and having an ionization tendency lower than an ionization tendency of the first metal layer;
a second metal layer formed on the barrier film and having an ionization tendency higher than the ionization tendency of the barrier film; and
a third metal layer on the second metal layer and having an ionization tendency lower than the ionization tendency of the second metal layer.

2. The semiconductor device according to claim 1, wherein the ionization tendency of the barrier film is lower than the ionization tendency of the third metal layer.

3. The semiconductor device according to claim 1, wherein the third metal layer is plated from a solution.

4. The semiconductor device according to claim 1, wherein the first metal layer and the second metal layer comprise aluminum, and the third metal layer comprises nickel.

5. The semiconductor device according to claim 1, wherein the first metal layer, the barrier film, the second metal layer, and the third metal layer are included in an emitter electrode of an insulated gate bipolar transistor.

6. The semiconductor device according to claim 1, wherein the barrier film comprises a metal.

7. The semiconductor device according to claim 1, wherein the barrier film comprises a semiconductor material.

8. The semiconductor device according to claim 7, wherein the semiconductor material is a polysilicon including a dopant.

9. The semiconductor device according to claim 1, wherein the barrier film includes at least one material selected from a group consisting of titanium, titanium nitride, tungsten, tungsten nitride, molybdenum, nickel, and copper.

10. A semiconductor device, comprising:
a semiconductor layer;
a first metal layer on the semiconductor layer and comprising aluminum;
a barrier film on first metal layer, and including at least one material selected from a group consisting of titanium, titanium nitride, tungsten, tungsten nitride, molybdenum, nickel, and copper;
a second metal layer on the barrier layer and comprising aluminum; and
a plated metal film on the second metal layer and comprising nickel.

11. The semiconductor device according to claim 10, wherein the first metal layer comprises at least one of aluminum, aluminum-silicon, and aluminum-silicon-copper.

12. The semiconductor device according to claim 10, wherein the first metal layer comprises aluminum-silicon.

13. The semiconductor device according to claim 10, wherein the first metal layer comprises aluminum-silicon-copper.

14. The semiconductor device according to claim 10, wherein the first metal layer, the barrier film, the second metal layer, and the plated metal film are included in an emitter electrode of an insulated gate bipolar transistor.

15. A method of manufacturing a semiconductor device, comprising:
forming a first metal layer on a semiconductor layer;
forming a barrier film on the first metal layer, the barrier film having an ionization tendency lower than an ionization tendency of the first metal layer;
forming a second metal layer on the barrier film, the second metal layer having an ionization tendency higher than the ionization tendency of the barrier film; and
forming a third metal layer on the second metal layer and having an ionization tendency lower than the ionization tendency of the second metal layer.

16. The method according to claim 15, wherein the barrier film is a polycrystalline silicon film including a dopant.

17. The method according to claim 15, wherein the barrier film is a metal film, and the ionization tendency of the barrier film is lower than the ionization tendency of the third metal layer.

18. The method according to claim 15, wherein
the first metal layer comprises aluminum,
the barrier film includes at least one material selected from a group consisting of titanium, titanium nitride, tungsten, tungsten nitride, molybdenum, nickel, and copper,
the second metal layer comprises aluminum, and
the third metal layer comprises nickel.

19. The method according to claim 15, wherein the third metal layer is plated from a solution.

20. The method according to claim 15, wherein the first metal layer, the barrier film, the second metal layer are included in an emitter electrode of an insulated gate bipolar transistor.
